(19) United States
(12) Patent Application Publication
(10) Pub. No.: US 2025/0271487 A1
(43) Pub. Date: Aug. 28, 2025

(54) SHIELD-FAULT DETECTION

(71) Applicant: Analog Devices International Unlimited Company, Limerick (IE)

(72) Inventor: Hector Enmanuel Alberti Arroyo, Limerick (IE)

(21) Appl. No.: 18/590,835

(22) Filed: Feb. 28, 2024

(51) Int. Cl. G01R 31/11; G01R 31/08; G01R 31/58

(52) U.S. Cl. CPC G01R 31/11; G01R 31/083; G01R 31/58

(57) ABSTRACT

There is provided a method of detecting a shield-fault along a cable or transmission line. In the method, the following steps are performed: obtaining at least one echo response of the cable or transmission line using time domain reflectometry, TDR, identifying a plurality of reflections in the echo response, determining the presence of a shield-fault by comparing locations of reflections in the at least one echo response. By doing this, the shield-faults, and their location, can be accurately determined in cables of different lengths using time domain reflectometry.

### TECHNICAL FIELD

The present disclosure relates to shield-fault detection, and in particular a method of detecting a shield-fault along a cable or transmission line.

### BACKGROUND

Faults may occur along cables or transmission lines, such as ethernet cables. Cables may comprise a shield, typically formed of metal, around the cable. The shield provides a level of protection against external electromagnetic interference, resulting in an improved signal-to-noise ratio for any data transmitted through the cable. However, shield-faults may occur due to aging, poor construction of the cable or transmission line, mechanical interaction with external objects, humidity, etc. These events may cause breaks in the shield or shield intrusions that can affect the signal integrity along the cable or transmission line. It is desirable to detect the occurrence of a shield-fault and its location along the cable or transmission line, allowing the fault to be fixed shortly after the fault is detected and reducing down time of the communication sent over the cable or transmission line.

### SUMMARY

According to a first aspect of the disclosure, there is provided a method for detecting a shield-fault in a cable or transmission line, the method comprising: obtaining at least one echo response of the cable or transmission line from a first end of the cable or transmission line using time domain reflectometry, TDR; identifying a plurality of reflections in the at least one echo response; and determining the presence of a shield-fault by comparing locations of reflections in the at least one echo response.

According to a second aspect of the disclosure, there is provided a method for detecting a shield-fault in a cable or transmission line, the method comprising: obtaining an open-circuit echo response of the cable or transmission line from a first end of the cable or transmission line using time domain reflectometry, TDR, whilst the cable or transmission line is open-circuited at a second end; obtaining a terminated echo response of the cable or transmission line from the first end of the cable or transmission line using TDR whilst the cable or transmission line is terminated at the second end; obtaining a short-circuit echo response of the cable or transmission line from the first end of the cable or transmission line using TDR whilst the cable or transmission line is short-circuited at the second end; identifying a plurality of reflections in the open-circuit echo response, the terminated echo response, and the short-circuit echo response; determining the presence of a shield-fault by comparing respective locations of reflections in the open-circuit, terminated and, short-circuit echo responses.

According to a third aspect of the disclosure, there is provided a method for detecting a shield-fault at the end of a cable or transmission line, the method comprising: obtaining a terminated echo response of the cable or transmission line from a first end of the cable or transmission line using time domain reflectometry, TDR; identifying a plurality of reflections in the echo response; determining the presence of a shield-fault, wherein a shield-fault is determined if: a negative polarity reflection is present at a first distance, the first distance equal to a length of the cable or transmission line; a positive polarity reflection is present at a second distance, the second distance equal to twice the cable length.

### BRIEF DESCRIPTION OF THE DRAWINGS

Aspects of the disclosure will now be described by way of example only and with reference to the accompanying drawings, wherein like reference numerals refer to like parts, and wherein:

FIG. 1 is a schematic representation of a time domain reflectometry system;

FIG. 2 is a flowchart of a method for detecting a shield-fault along a cable or transmission line;

FIG. 3 is a graph of echo responses of a number of cables or transmission lines;

FIG. 4 is a schematic representation of a time domain reflectometry system including a device or load;

FIG. 5 is a schematic representation of a time domain reflectometry system including a device or load and a switch;

FIG. 6a is a flowchart of a method for detecting a shield-fault along a cable or transmission line using an open-circuit and terminated echo response;

FIG. 6b is a graph of echo responses of a terminated echo response and an open-circuit echo response of a cable that includes a shield-fault at a first location;

FIG. 7 is a flowchart of a method for detecting a shield-fault along a cable or transmission line using a short-circuit and terminated echo response;

FIG. 8a is a flowchart of a method for detecting a shield-fault along a cable or transmission line using an open-circuit and terminated echo response;

FIG. 8b is a graph of echo responses of a terminated echo response and an open-circuit echo response of a cable that includes a shield-fault at a second location;

FIG. 9 is a flowchart of a method for detecting a shield-fault along a cable or transmission line using an open-circuit echo response or a terminated echo response;

FIG. 10 is a flowchart of a method for detecting a shield-fault along a cable or transmission line using echo responses obtained from opposite ends of a cable or transmission line;

FIG. 11 is a schematic representation of a time domain reflectometry system including two time-domain reflectometers coupled to opposite ends of the cable or transmission line;

FIG. 12 is a flowchart of a method for determining the length of the cable or transmission line;

FIG. 13 is a graph showing the normalised representations of a plurality of reflections of FIG. 3.

### DETAILED DESCRIPTION

A time domain reflectometer (TDR) may be used to measure impedance mismatches along a cable through the signal reflections these create. The time domain reflectometer transmits a first signal along the cable and receives an echo response showing a number of reflections. Theoretically, in a perfect cable that is properly terminated there will be no reflections, indicating that there are no faults. Where there are faults, a number of reflections may be detected.

This TDR method, however, is normally used to detect simple faults on the transmission line.

In wired installations using shielded differential pair cables, it is common for part of the braid of the shield to come into contact with at least one of the data lines. This may result in either constant or intermittent signal integrity issues. This type of fault can be hard to detect without special equipment. A common approach to detect such events is monitoring the current on the shield of the cable. However, this method does not show the location of the shield fault.

Some cables or transmission lines allow communication over long distances. For example, the 10BASE-T1L standard enables communication over cables of up to 1 km. Detecting the presence of a fault allows the cable to be replaced. However, replacing long cables may be uneconomical, and as such it is valuable to know the location of the shield-fault within the cable, allowing only a short length of cable to be removed and replaced.

Using a TDR approach can show the exact location where there may be a fault, thus making it easier for maintenance engineers and technician to repair the fault. This can be done either during commissioning or as preventive and corrective maintenance. Often, including some form of TDR on a transceiver, such as a 10BASE-T1L ethernet physical layer, comes with the advantage of the reutilization of already existing blocks in the transceiver itself, such as its transmitter, receiver and other circuitry that can be reutilized to produce a TDR response. This allows the TDR method to diagnose the communication system including the cable, without disconnecting the cable itself, thus covering the whole signal path of the communication signal and the correct frequencies of interest for the specific transceiver. In some cases, this may allow diagnostics to be performed even without interrupting the normal data transmission. This may be referred to as background diagnostics, or background shield-fault detection.

For shield intrusion (a shield fault caused by short circuiting the shield to a data line in a differential transmission line) using TDR offers the advantage of a simple detection method that relies on the signature of the reflections in the TDR response. Where a shield to data line short exists, a common short detector may not detect this as a fault if the impedance mismatch does not produce a reflection with a great enough amplitude to be detected, and if detected, it may be interpreted incorrectly. As the signal travels along a cable and it finds the shield shorted (DC or AC) to the data line, the TDR response will show an impedance mismatch. An impedance mismatch will be represented by a reflection or peak in the TDR echo response. However, the signal may continue to travel through the shield for a distance equal to the shield length, and also through the differential pair (if the shield intrusion occurs somewhere along the cable before its total length). The signal traveling through the shield produces another impedance mismatch, represented by a peak or reflection once the signal reaches the end the shield. This signature allows an accurate detection and determination of the exact type and location of the fault so that an installation and maintenance engineer or technician can more easily resolve any underlaying issue with a communication system using the transmission line.

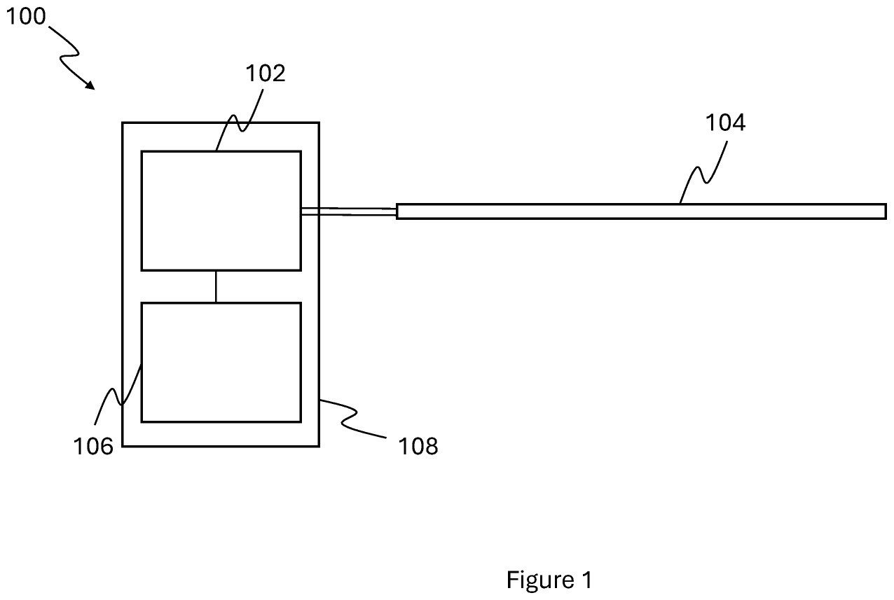

FIG. 1 shows a schematic representation of a time domain reflectometry system 100. The system 100 includes a time domain reflectometer 102. The time domain reflectometer 102 is coupled to a cable or transmission line 104 and is configured to output a signal to the cable or transmission line 104 and receive an echo response including reflections. The coupling between the time domain reflectometer 102 and the cable or transmission line 104 may be a differential connection. The cable 104 may comprise a shield and two data lines. The TDR 102 may be connected to the two data lines of the cable or transmission line 104. The time domain reflectometer 102 is coupled to a control system 106. The time domain reflectometer provides the received echo response to the control system 106.

The time domain reflectometer 102 and the control system 106 may be part of a larger system 108 which combines the capabilities of both systems.

The system 108 is coupled to a first end of the cable or transmission line 104 and configured to obtain at least one echo response of the cable or transmission line 104 using time domain reflectometry. However, the system 108 may be additionally or alternatively be coupled to the second end of the cable or transmission line 104 and configured to obtain at least one echo response of the cable or transmission line 104 using time domain reflectometry.

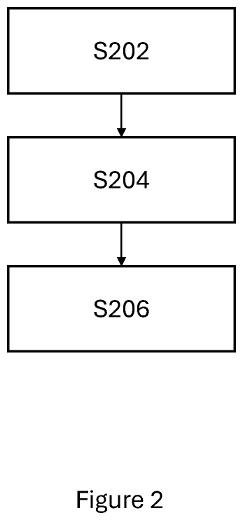

FIG. 2 shows a flowchart of a method for detecting a shield-fault along a cable or transmission line. The method may be performed by the control system 106 of the system 108. Alternatively, the method may be performed by a separate control system that is not couped to the cable, but that receives the echo response from the time-domain reflectometer 102.

At step S202, at least one echo response of the cable or transmission line 104 is obtained using time domain reflectometry. The echo response may be obtained from the first end of the cable or transmission line 104 or from the second end of the cable or transmission line 104. Obtaining an echo response may comprise receiving an echo response from an external system, external time-domain reflectometer or memory comprising previously stored echo responses. Obtaining an echo response may alternatively comprise performing a time domain reflectometry measurement.

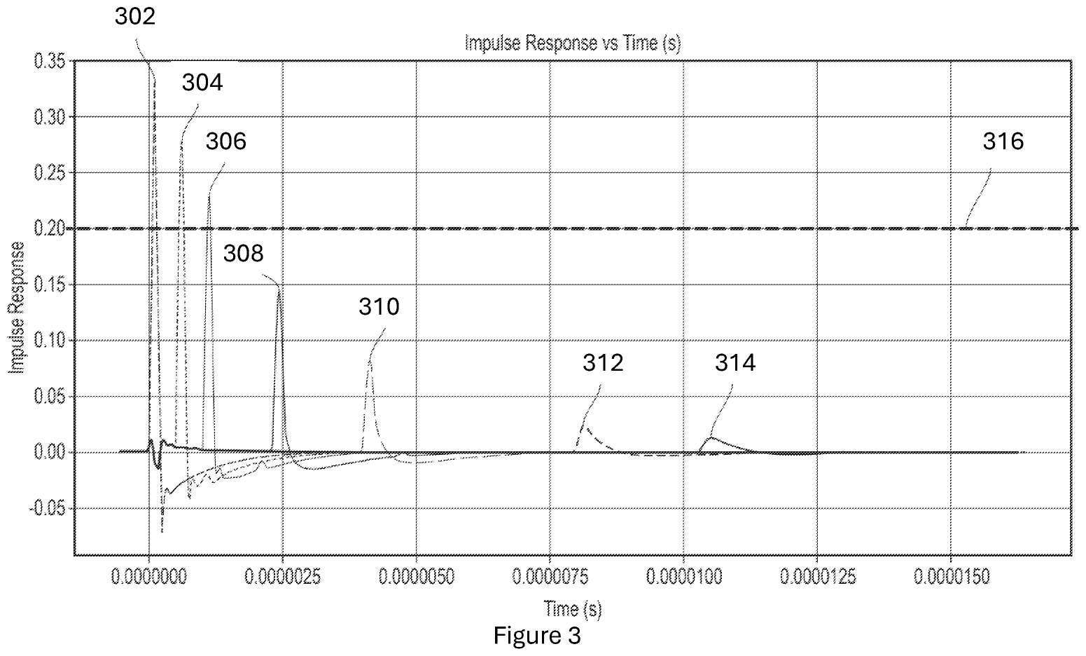

At step S204, a plurality of reflections are identified in the at least one echo response of the cable or transmission line 104. FIG. 3 shows echo responses of a number of cables, including reflections 302-314 at different locations or distances along the cables. The X axis shows the time at which the reflection was detected, with a higher time indicating a greater distance along the cable 104 from the time domain reflectometer 102. As such, the X axis may also be considered to directly indicate the distance of the reflection from the time domain reflectometer 102, or from the end of the cable or transmission line 104 at which the echo response was generated.

The Y axis shows the impulse response or amplitude of the reflection. Each reflection may have a different amplitude. The attenuation of the cable results in each of the reflections having a different amplitude and shape. The greater the distance the reflection is along the cable 104 from the time domain reflectometer 102, the lower the peak impulse response or peak amplitude of the reflection. Other factors may also affect the amplitude of the reflection, such as the attenuation of the cable per unit of length, the cable's impedance and the cable length.

Identifying the plurality of reflections may comprise determining the locations of the reflections (i.e. the distance from the end of the cable or transmission line at which the reflection is found or at which the peak amplitude of the reflection occurs). The location of the reflection may be considered to be a time at which the reflection is received, or a distance along the cable or transmission lines 104. The distance may be computed through knowledge of the speed of propagation of the signal through the cable.

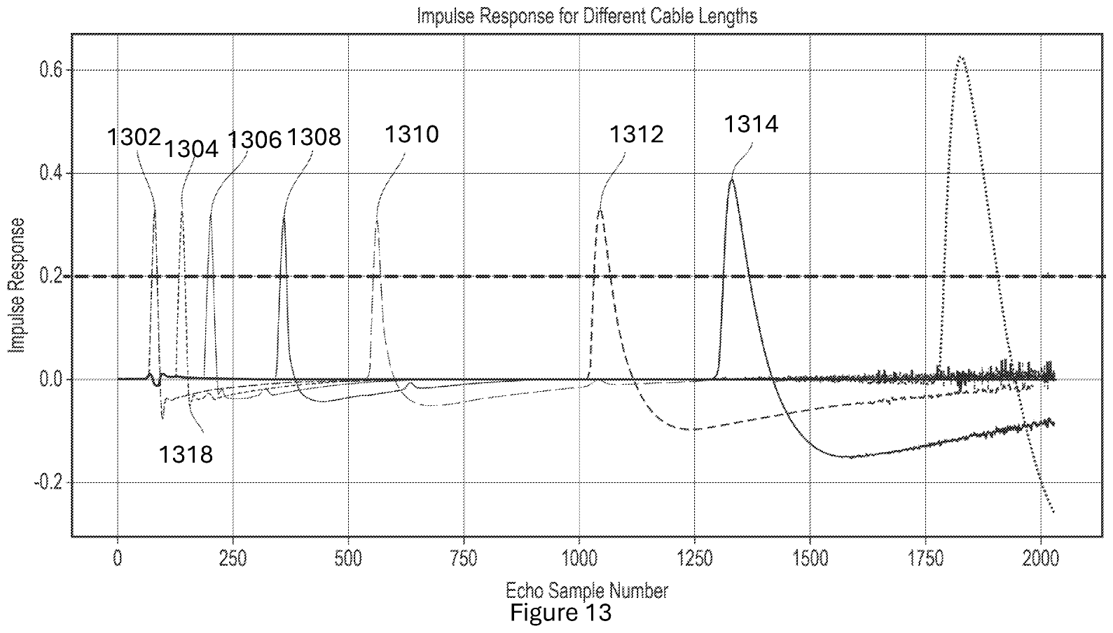

To ensure that noise is not considered, a threshold 316 may be used to determine valid reflections. Reflections may be considered valid if they are above the threshold 316. The threshold may be determined through knowledge of the attenuation of the cable, such that a reflection with a peak (absolute) amplitude which is above the threshold is considered a valid reflection. As the attenuation of the cable results in each reflection found at a different location having a different amplitude, the reflections or the threshold 316 may be normalised relative to the attenuation of the cable. Validation and normalisation of reflections is outlined further with respect to FIG. 13. However, the validation and normalisation are optional, and the method may be performed without validation or normalisation of the echo responses.

At step S206, a shield fault is determined to be present, or not present, by comparing locations of reflections in the at least one echo response obtained in step S202. This may comprise comparing the locations of multiple reflections in the same echo response, or comparing the locations of reflections in different echo responses. The presence of reflections at different locations in the different echo response types may indicate the presence of, or the absence of, a shield fault.

Reflections may be created due to shield-faults. For example, where the shield is shorted to one or more of the data lines of the cable or transmission line 104, an impedance mismatch is present due to the parallel combination of the data line and the shield. This impedance mismatches causes a reflection to be present in the echo response of the TDR. A single shield fault may cause multiple reflections to be present in the echo response at different locations or times and with different characteristics. For example, where the transmitted TDR signal propagates along the cable, an impedance mismatch and thus reflection may be seen on the outgoing and return travel of the TDR signal. As such, comparing the locations and types of reflections seen allows a shield-fault to be detected and distinguished from other faults in the cable or transmission line 104.

Different types of echo response may be generated by modifying the connections of the second end of the cable or transmissions line 104.

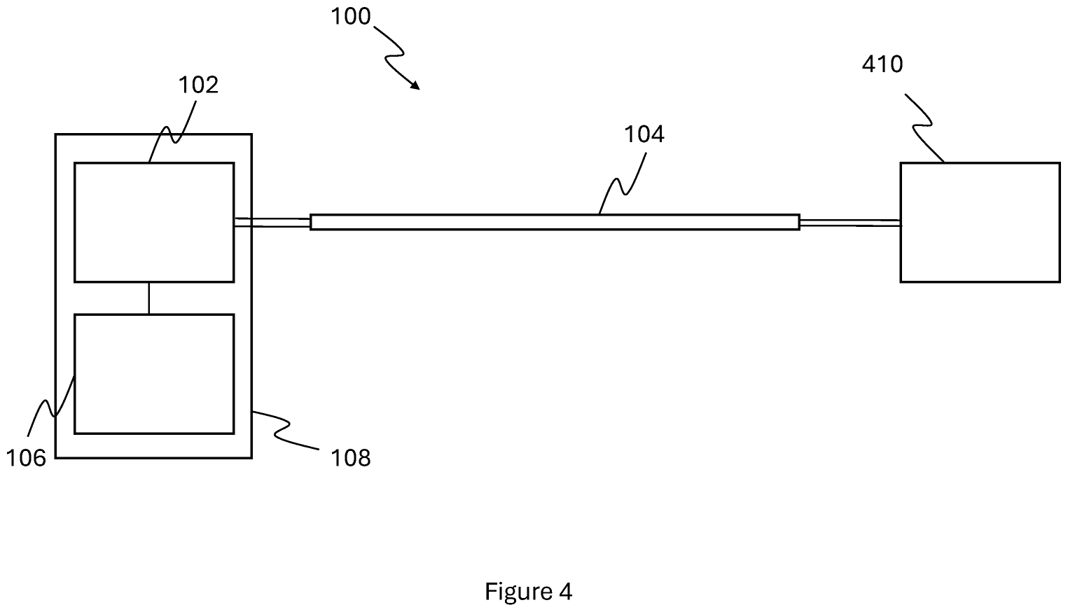

FIG. 4 shows the time domain reflectometry system 100 shown in FIG. 1, further including a load or device 410 coupled to the second end of the cable or transmission line 104. The load or device 410 may be a communication system or receiver that is operable to communicate using the cable or transmission line 104. The load or device 410 may be a second time domain reflectometer.

A terminated echo response may represent the echo response acquired by the time domain reflectometer 102 from the first end of the cable or transmission line 104 whilst the second end is terminated using a load 410. The load 410 may be a matched load, matched to the impedance of the cable or transmission line 104. As such, the load 410 may have the same impedance as the cable or transmission line 104. The terminated echo response may therefore be considered to be a properly terminated or impedance matched echo response.

A short-circuit echo response may represent the echo response acquired by the time domain reflectometer 102 from the first end of the cable or transmission line 104 whilst the second end is short-circuited. In this situation, the device 410 may be arranged to short the second end of the cable or transmission line 104.

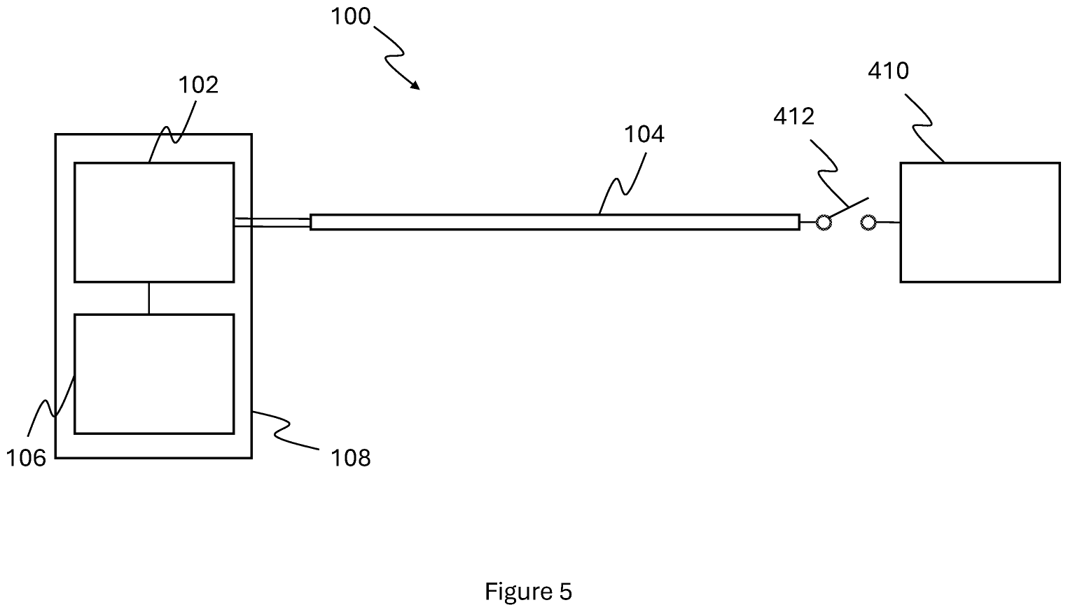

An open-circuit echo response may represent the echo response acquired by the time domain reflectometer 102 from the first end of the cable or transmission line 104 whilst the cable or transmission line is open-circuited at the second end. This may be achieved by decoupling or disconnecting the second end of the cable or transmission line from the load or device 410. As shown in FIG. 5, this may be achieved using a switch or relay 412 coupled between the cable or transmission line 104 and the device or load 410. Opening the switch disconnects the second end of the cable or transmission line from the device or load, allowing an open-circuit echo response to be acquired. Alternatively, the open-circuit echo response may be obtained whilst the device 410 is powered off.

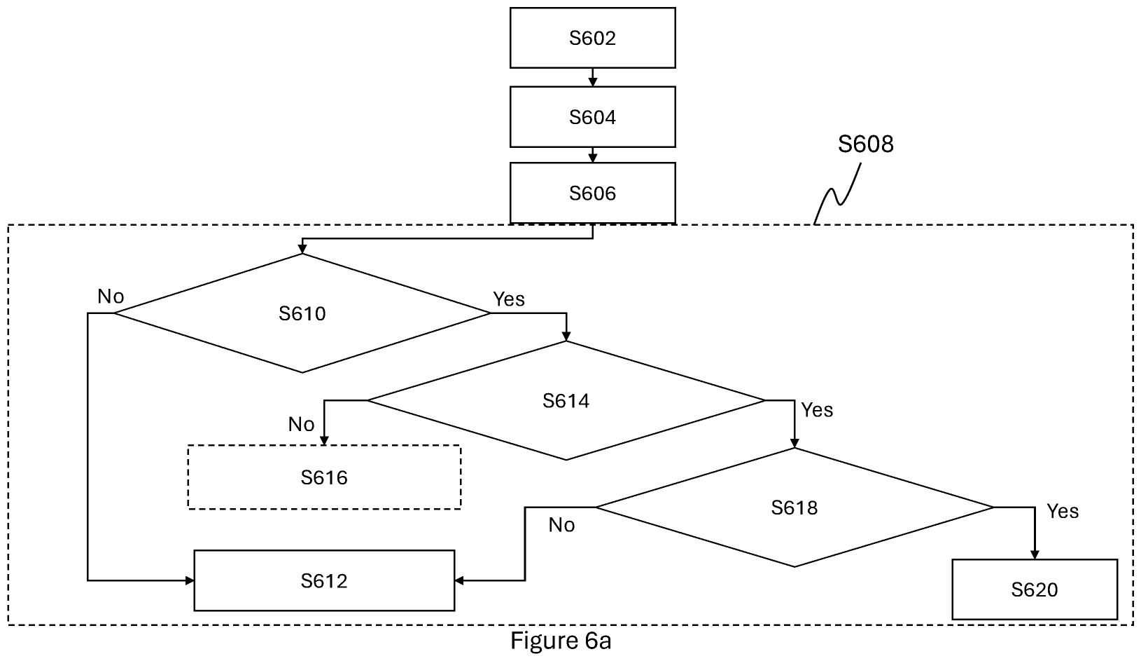

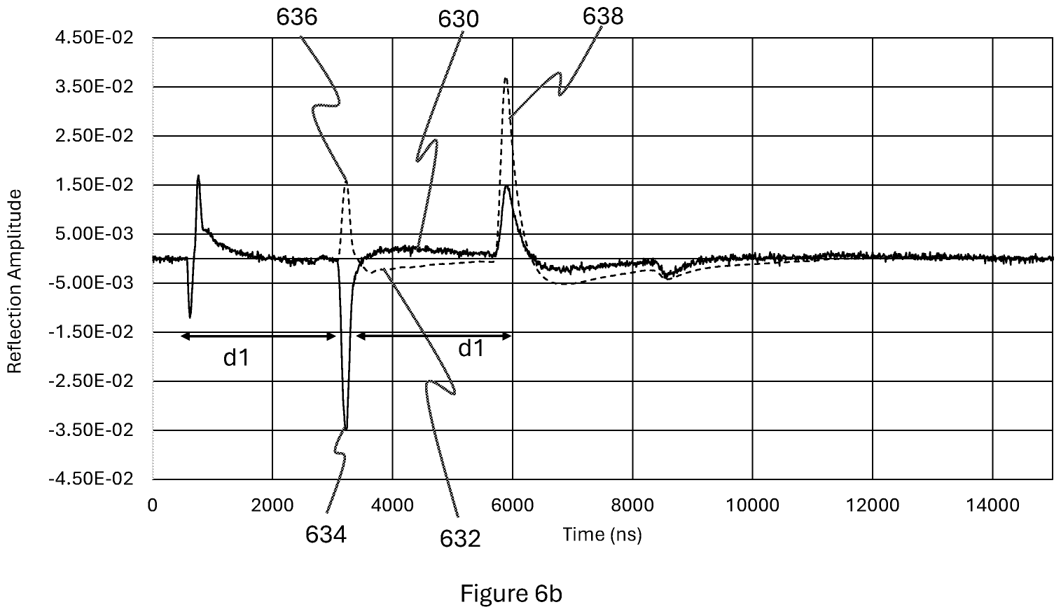

FIG. 6a is a flowchart of a method for detecting a shield-fault along a cable or transmission line. The method may be performed by the control system 106 of the time domain reflectometry system 106, or by other suitable control systems, microprocessors, or systems.

In step S602, an open-circuit echo response of the cable or transmission line is obtained from a first end of the cable or transmission line using time domain reflectometry whilst the cable or transmission line is open-circuited at a second end.

In step S604, a terminated echo response of the cable or transmission line is obtained from the first end of the cable or transmission line using time domain reflectometry whilst the cable or transmission line is properly terminated at the second end.

In step S606 a plurality of reflections are identified in the open-circuit echo response and the terminated echo response.

In step S608 the presence, or absence, of a shield-fault is determined by comparing respective locations of reflections in the open-circuit echo response and the terminated echo response. Step S608 comprises one or more of steps S610-S620.

Step S610 comprises determining whether a first reflection with a negative polarity is present in the terminated echo response. The first reflection is located at a first distance along the cable or transmission line 104. If no first reflection is detected or determined, then no shield-fault is detected, and the method moves to step S612.

When the method moves to step S612, the method may finish, and the remaining steps S614-S620 may not be performed, as it has been determined that a shield-fault is not present.

If the presence of a first reflection is determined in block S610, the method moves on to step S614. Step S614 comprises determining whether a second reflection having a positive or negative polarity is present in the open-circuit echo response at the first distance along the cable or transmission line 104 with a different amplitude compared to the first reflection. If the presence of a second reflection with these properties is not determined, then the method moves to step S616.

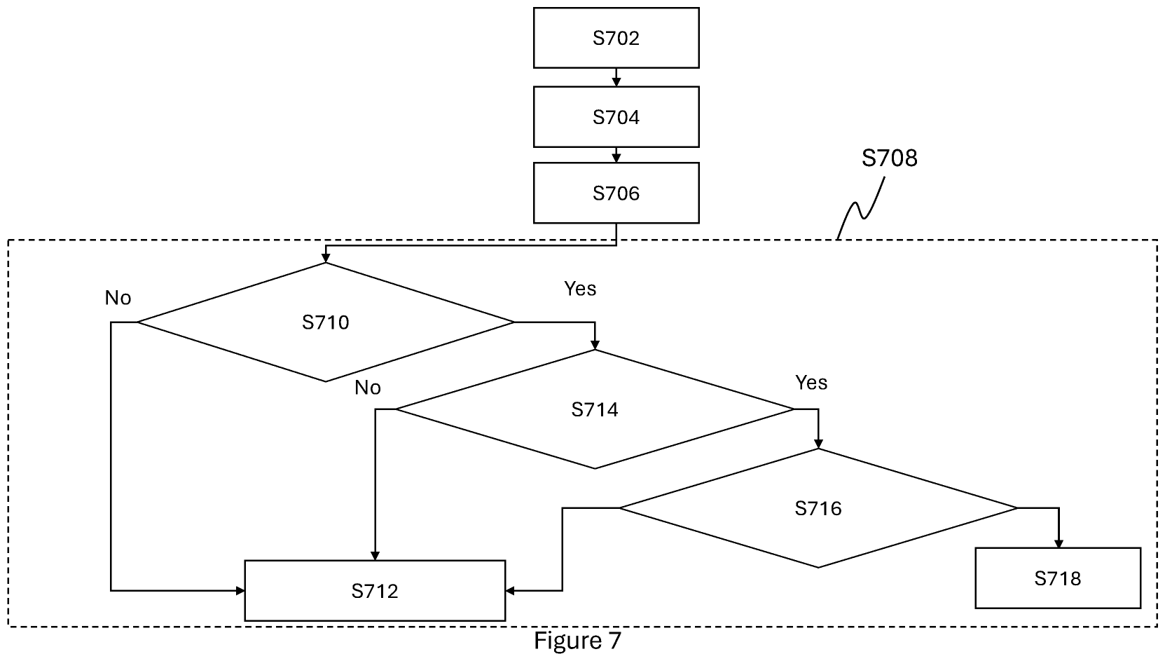

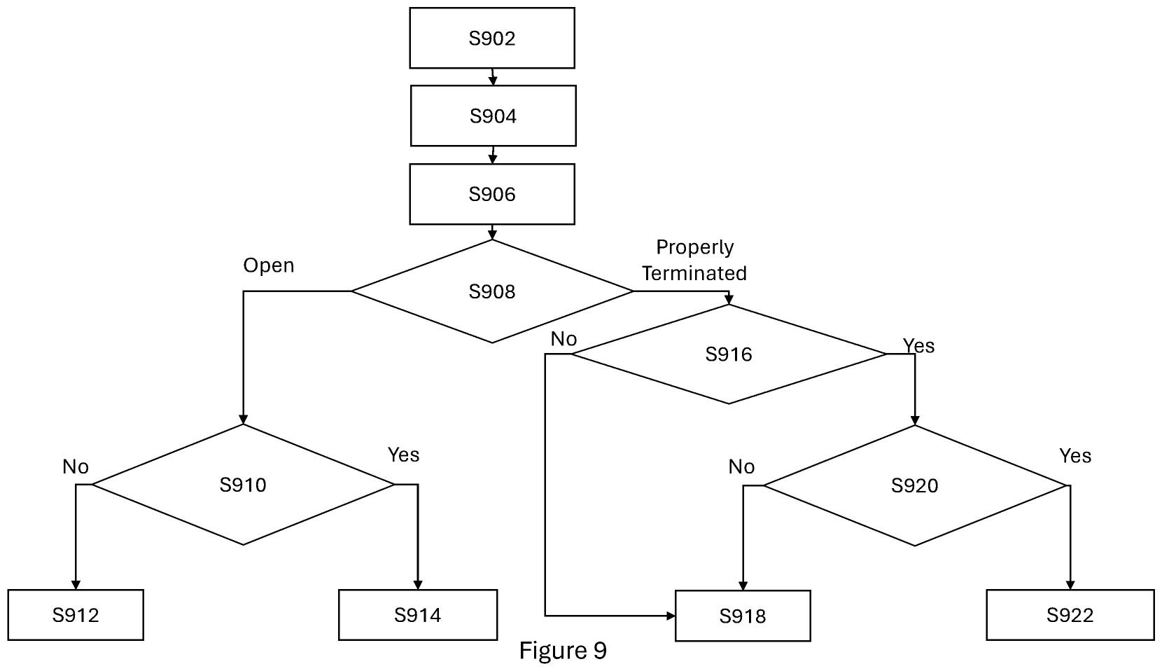

In step S616, it cannot be determined whether a shield-fault is present or not present without knowing the length of the cable or transmission line 104 or obtaining a short-circuit echo response. Instead, the methods of FIG. 7 (in which a short-circuit echo response is obtained and considered) or FIG. 9 (in which the length of the cable or transmission line is known) may be used to determine the presence or absence of a shield-fault. If a change in the termination of the cable or transmission line 104 does not change the shape and amplitude of the reflection, then the fault is not a shield fault. Instead, it is another type of impedance mismatch, a normal reflection, or measurement noise.

If a second reflection with the referenced properties is present in the open-circuit echo response, the method moves on to step S618. Step S618 comprises determining whether a third reflection is present with a positive polarity in either of the terminated or open-circuit echo responses at a second distance along the cable or transmission line 104. The second distance is equal to twice the first distance considered in steps S610 and S614. If the presence of a third reflection with these properties is not present, the method moves on to step S612, and no shield-fault is detected in the cable or transmission line.

If the presence of a third reflection with the referenced properties is determined in either the terminated or open-circuit echo responses, then the method moves on to Step S620. As the presence of first, second and third reflections has been determined, a shield fault is determined to be present in the cable or transmission line 104 and the method ends.

The shield fault is located at the first distance from the time domain reflectometer 102. In other words, the shield-fault is located the first distance or length along the cable or transmission line 104 from the first end of the cable or transmission line 104.

Knowing the location of the shield fault may allow a portion of the cable or transmission line to be repaired or replaced. Alternatively, a connector may be replaced, if the connector is at the location of the determined shield fault. If the location was not known, the entire cable or transmission line may have to be replaced.

Where multiple reflections are present in the echo responses, the steps present in step S608 of the method may be repeated, with each of the reflections considered. For example, if three reflections are present in the terminated echo response, then step S610 may be repeated for each of these reflections. Each of the reflections may be at different locations along the cable or transmission line 104, and as such the first distance considered for each of these reflections is different. Steps S614 and S618 check for the presence of reflections at distances that are related to the first distance (either at the first distance or at a second distance that is twice the first distance). As such, considering a different reflection in step S610 results in the consideration of the presence or absence of reflections at different locations in steps S614 and S618.

The steps of any method may also be performed in different orders. For example, the method of FIG. 6a may perform step S614 before step S610. Further, the steps may be performed concurrently or at the same time.

FIG. 6b shows a graph of example echo responses of a cable or transmission line 104 taken from a first end of the cable or transmission line 104. The graph includes a terminated echo response 630 of the cable or transmission line whilst the cable or transmission line is terminated (represented by the solid line on the graph). The graph further includes an open-circuit echo response 632 of the cable or transmission line whilst the cable or transmission line is open-circuited at the second end (represented by the dashed line on the graph).

The terminated echo response 630 includes a first reflection 634 with a negative polarity in the terminated echo response 630. The first reflection 634 is located at a first distance d1 along the cable or transmission line 104. This corresponds to the determination made in step S610 of FIG. 6a.

The open-circuit echo response comprises a second reflection 636 having a positive polarity at the first distance d1 along the cable or transmission line 104 with a different amplitude compared to the first reflection. This corresponds to the determination made in step S614 of FIG. 6a.

A third reflection 638 is present in the terminated 630 and open-circuit 632 echo responses at a distance twice that of the first distance (2*d1). This corresponds to the determination made in step S618 of FIG. 6a. As such, a shield-fault is determined to be present in the cable or transmission line.

FIG. 7 is a flowchart of a method for detecting a shield-fault along a cable or transmission line. The method may be performed by the control system 106 of the time domain reflectometry system 108, or by other suitable control systems, microprocessors, or systems.

In step S702, a short-circuit echo response of the cable or transmission line is obtained from a first end of the cable or transmission line using time domain reflectometry whilst the cable or transmission line is short-circuited at the second end.

In step S704, a terminated circuit echo response of the cable or transmission line is obtained from the first end of the cable or transmission line using time domain reflectometry whilst the cable or transmission line is terminated at the second end.

In step S706 a plurality of reflections are identified in the short-circuit echo response and the terminated echo response.

In step S708 the presence, or absence, of a shield-fault is determined by comparing respective locations of reflections in the short-circuit echo response and the terminated echo response. Step S708 comprises one or more of steps S710-S718.

Step S710 operates in the same manner as step S610 of FIG. 6a. Step S710 comprises determining whether a first reflection with a negative polarity is present in the terminated echo response. The first reflection is located at a first distance along the cable or transmission line 104. If no first reflection is detected or determined, then no shield-fault is detected, and the method moves to step S712.

When the method moves to step S712, the method may finish, and the remaining steps S714-S718 may not be performed, as it has been determined that a shield-fault is not present.

If the presence of a first reflection is determined in block S710, the method moves on to step S714. Step S714 comprises determining whether a second reflection having a negative polarity is present in the short-circuit echo response at the first distance along the cable or transmission line 104 with a larger or greater magnitude amplitude (absolute value) compared to the first reflection. The second reflection should also be the last reflection determined to be present in the short-circuit echo response. The last reflection may be the last valid reflection (i.e. the last non-noise related reflection). Last may mean that the reflection is the furthest distance along the cable or transmission line 104 from the first end. If the presence of a second reflection with these properties is not determined, then the method moves to step S712 and no shield-fault is determined to be present.

If a second reflection with the referenced properties is present in the short-circuit echo response, the method moves on to step S716. Step S716 comprises determining whether a third reflection is present with a positive polarity in the terminated echo responses at a second distance along the cable or transmission line 104. The second distance is equal to twice the first distance considered in steps S710 and S714. If the presence of a third reflection with these properties is not present, the method moves on to step S712, and no shield-fault is detected in the cable or transmission line.

If the presence of a third reflection with the referenced properties is determined in either the terminated or short-circuit echo responses, then the method moves on to Step S718. As the presence of first, second and third reflections has been determined, a shield fault is determined to be present in the cable or transmission line 104. The shield fault is located at the first distance from the time domain reflectometer 102. In other words, the shield-fault is located the first distance or length along the cable or transmission line 104 from the first end of the cable or transmission line 104.

As noted with respect to FIG. 6a, where multiple reflections are present in the echo responses, the steps present in step S708 of the method may be repeated, with each of the reflections considered. For example, if three reflections are present in the terminated echo response, then the step S710 may be repeated for each of these reflections. Each of the reflections may be at different locations along the cable or transmission line 104, and as such the first distance considered for each of these reflections is different. Steps S714 and S716 check for the presence of reflections at distances that are related to the first distance (either at the first distance or at a second distance that is twice the first distance). As such, considering a different reflection in step S710 results in the consideration of the presence or absence of reflections at different locations in steps S714 and S716.

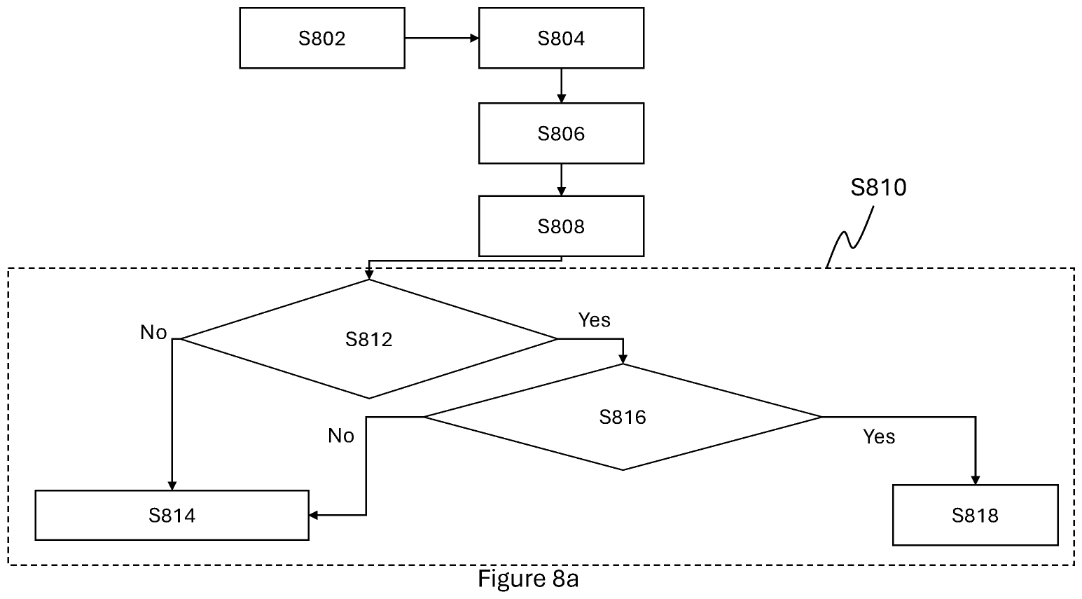

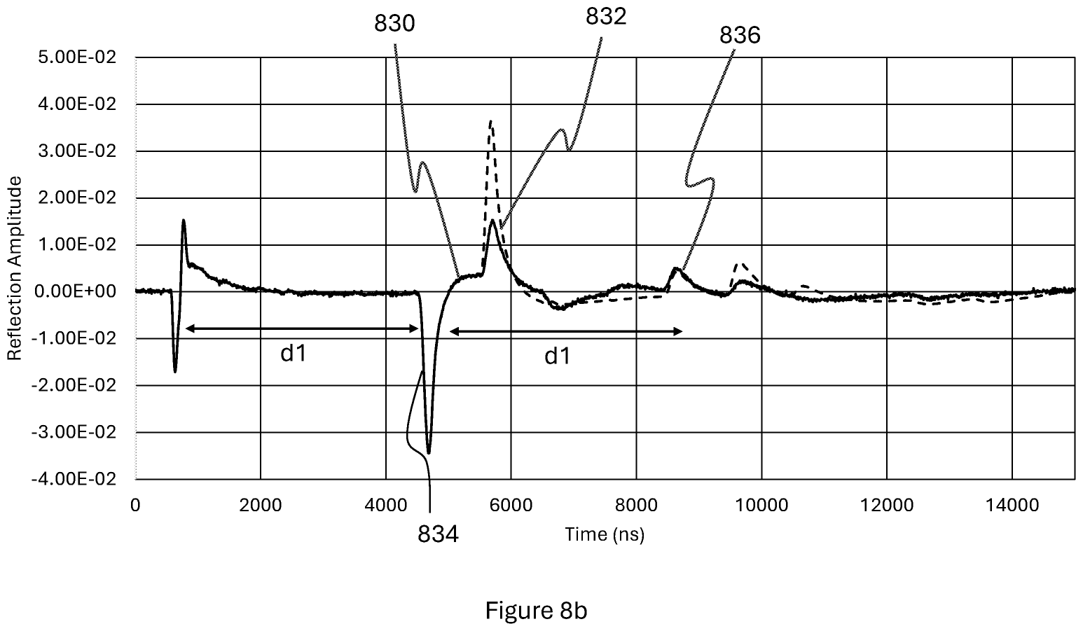

FIG. 8a is a flowchart of a method for detecting a shield-fault along a cable or transmission line. The method may be performed by the control system 106 of the time domain reflectometry system 108, or by other suitable control systems, microprocessors, or systems.

In step S802, an open-circuit echo response of the cable or transmission line 104 is obtained from a first end of the cable or transmission line using time domain reflectometry whilst the cable or transmission line is open-circuited at the second end.

In step S804, a terminated circuit echo response of the cable or transmission line is obtained from a first end of the cable or transmission line using time domain reflectometry whilst the cable or transmission line is terminated at the second end.

In step S806, a plurality of reflections are identified in the open-circuit echo response and the terminated echo response.

In step S808, the length of the cable is obtained. The length of the cable or transmission line may be provided by a user or operator of the time domain reflectometry system 100 comprising the cable or transmission line 104. Alternatively, the length of the cable may be obtained through the determination of the locations of reflections in the echo responses.

In step S810 the presence, or absence, of a shield-fault is determined by comparing respective locations of reflections in the open-circuit echo response and the terminated echo response. Step S810 comprises one or more of steps S812-S818.

Step S812 comprises determining whether a first reflection with a negative polarity is present in the terminated echo response. The first reflection is located at a first distance along the cable or transmission line 104. Step S812 further comprises determining whether a second reflection with a negative polarity is present in the open-circuit echo response at the first distance along the cable or transmission line, the second reflection having the same amplitude as that of the first reflection. The second reflection should also have the same characteristics as the first reflection. Characteristics may include the slope or gradient of the reflection, the width of the reflection and the amplitude of reflection. If the reflections are the same, such that the reflections would overlap when presented on a graph of the echo responses, then they may be considered to have the same characteristics. If the presence of a first reflection and/or a second reflection is not determined, then no shield-fault is detected, and the method moves to step S814.

When the method moves to step S814, the method may finish, and the remaining steps S816-S818 may not be performed, as it has been determined that a shield-fault is not present.

If the presence of a first reflection and a second reflection is determined in block S812, the method moves on to step S816. Step S816 comprises determining whether a third reflection having a positive polarity is present in the terminated echo response at a second distance along the cable or transmission line 104. The second distance is equal to twice the first distance. Step S816 further comprises determining whether a fourth reflection with a positive polarity is present in the open-circuit echo response at the second distance along the cable or transmission line. If neither of the third reflection and the fourth reflection are determined to be present, then no shield-fault is detected, and the method moves to step S814.

If the presence of first, second, and at least one of the third or fourth reflections are determined, then the method moves on to step S818 and a shield fault is determined to be present and located at the first distance along the cable or transmission line.

As noted with respect to FIGS. 6 and 7, where multiple reflections are present in the echo responses, the steps present in step S810 of the method may be repeated, with each of the reflections considered. For example, if three reflections are present in the terminated echo response or the open echo response, then the step S812 may be repeated for each of these reflections. Each of the reflections may be at different locations along the cable or transmission line 104, and as such the first distance considered for each of these reflections is different. Step S816 checks for the presence of reflections at distances that are related to the first distance (at twice the first distance). As such, considering a different reflection in step S812 results in the consideration of the presence or absence of reflections at different locations in step S816.

FIG. 8b shows a graph of example echo responses of a cable or transmission line 104 taken from a first end of the cable or transmission line 104. The graph includes a terminated echo response 830 of the cable or transmission line 104 whilst the cable or transmission line 104 is terminated (represented by the solid line on the graph). The graph further includes an open-circuit echo response 832 of the cable or transmission line whilst the cable or transmission line is open-circuited at the second end (represented by the dashed line on the graph).

The terminated echo response 830 includes a first reflection 834 with a negative polarity at a first distance d1 along the cable or transmission line. The open circuit echo response 832 comprises a second reflection with a negative polarity having the same amplitude as that of the first reflection 834. The second reflection also has the same characteristics as the first reflection. As such, the second reflection cannot be differentiated from the first reflection in the graph of FIG. 8b, due to their overlapping nature. This corresponds to the determination made in step S812 of FIG. 8a.

Further, a third reflection 836 having a positive polarity is present the terminated echo response 830 at a second distance along the cable or transmission line 104 that is equal to twice the first distance (2*d1). As a third reflection is present, a shield fault is determined to be present. This corresponds to the determination made in step S816. As such, a shield fault is determined to be present in the cable or transmission line 104.

FIG. 9 is a flowchart of a method for detecting a shield-fault along a cable or transmission line. The method may be performed by the control system 106 of the time domain reflectometry system 108, or by other suitable control systems, microprocessors, or systems.

In step S902, an open-circuit echo response of the cable or transmission line 104 or a terminated echo response of the cable or transmission lines 104 is obtained from a first end of the cable or transmission line using time domain reflectometry whilst the cable or transmission line is open-circuited or terminated at the second end.

In step S904 a plurality of reflections are identified in the open-circuit echo response or the terminated echo response.

In step S906, the length of the cable or transmission line 104 is obtained. The length of the cable or transmission line may be provided by a user or operator of the time domain reflectometry system 100 comprising the cable or transmission line 104. Alternatively, the length of the cable may be obtained through the determination of the locations of reflections in the echo responses.

In step S908, it is determined whether the echo response is an open-circuit or terminated echo response. If the echo response is an open-circuit echo response, the method proceeds to step S910. If the echo response is a terminated echo response, the method proceeds to step S916. The method steps following step S908 may be considered to be separate methods, with one method relating to analysis of the open-circuit echo response and one method relating to analysis of the closed-circuit echo response. As such, these methods may be performed either as a combined single method or separately.

In step S910, the method comprises determining whether a first reflection with a positive polarity is present in the open-circuit echo response at a first distance. The first distance is approximately or substantially equal to twice the length of the cable. The first distance may be equal to a distance twice that of a value of 90%-110% of the length of the cable, between 95-105% of the length of the cable, between 98-102% of the length of the cable or between 99-101% of the length of the cable of the length of the cable. The first distance may be twice the distance of the length of the cable. If a first reflection having these properties is not present in the open-circuit echo response, then no shield fault is detected, and the method moves to step S912.

When the method moves to step S912, the method may finish, as it has been determined that a shield-fault is not present.

If a first reflection is determined to be present in the open-circuit echo response having the referenced properties, then a shield fault is determined to be present at the end of the cable, and the method moves to step S914. The end of the cable is the second end of the cable or transmission line 104, or the opposite end to the end at which the time domain reflectometer 102 is coupled. The end of the cable is a distance equal to half of the first distance along the cable.

The method may finish once step S914 has been reached. Alternatively, the method may check for shield faults using a properly terminated echo response by following steps S916-S922.

In step S916, the method comprises determining whether a second reflection with a negative polarity is present in the terminated echo response at a second distance. The second distance is approximately equal to the length of the cable or transmission line 104. The second distance may be equal to a distance of 90%-110% of the length of the cable, between 95-105% of the length of the cable, between 98-102% of the length of the cable or between 99-101% of the length of the cable. The second distance may be equal to the length of the cable or transmission line 104. If the presence of a second reflection is not determined, then no shield-fault is detected, and the method moves to step S918.

When the method moves to step S918, the method may finish, and the remaining steps S920-S922 may not be performed, as it has been determined that a shield-fault is not present.

If the presence of a second reflection is determined in step S916, the method moves on to step S920. In step S920, the method comprises determining whether a third reflection with a positive polarity is present in the terminated echo response at a third distance. The third distance is approximately equal to a value twice that of the length of the cable or transmission line 104. The third distance may be equal to a distance twice that of a value of 90%-110% of the length of the cable, between 95-105% of the length of the cable, between 98-102% of the length of the cable or between 99-101% of the length of the cable. The third distance may be equal to twice the length of the cable or transmission line 104. If the presence of a third reflection is not determined, then no shield-fault is detected, and the method moves to step S918.

If the presence of a third reflection is determined in step S920, then the method moves on to step S922 as a shield fault has been determined to be present at the end of the cable or transmission line 104. The end of the cable is the second end of the cable or transmission line 104, or the opposite end to the end at which the time domain reflectometer 102 is coupled. The end of the cable is a distance equal to the second distance along the cable.

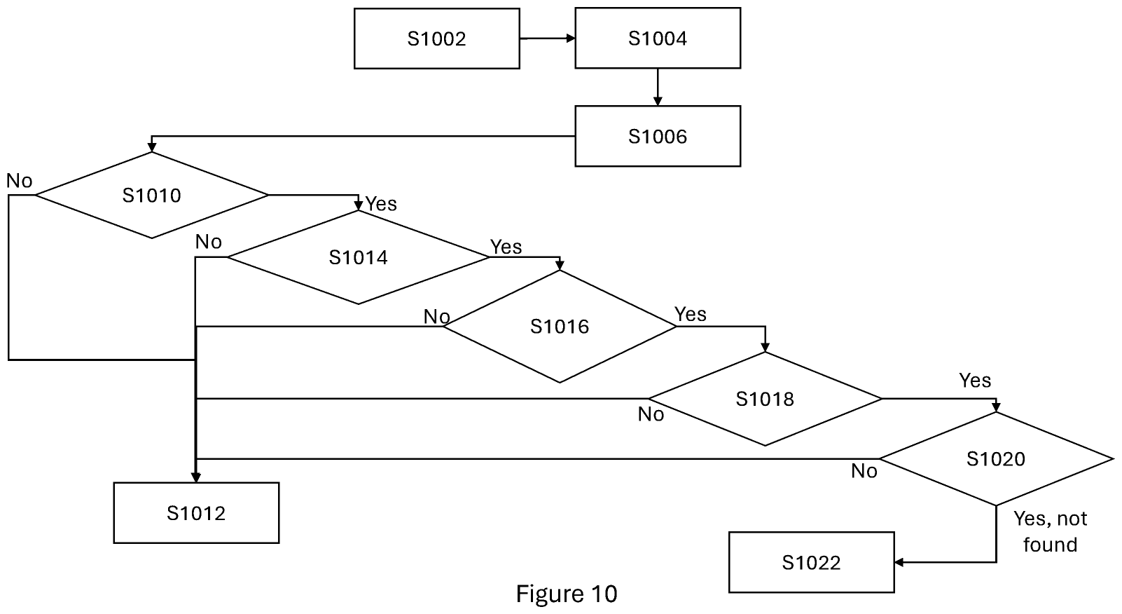

FIG. 10 is a flowchart of a method for detecting a shield-fault along a cable or transmission line. The method may be performed by the control system 106 of the time domain reflectometry system 108, or by other suitable control systems, microprocessors, or systems.

In step S1002, a first echo response of the cable or transmission line 104 is obtained from a first end of the cable or transmission line 104 using time domain reflectometry whilst the cable or transmission line is any of open-circuited, short-circuited or terminated at the second end. This first echo response may be obtained by a time domain reflectometer 102 coupled to the first end of the cable or transmission line 104.

In step S1004 a second echo response of the cable or transmission line 104 is obtained from a second end of the cable or transmission line 104 using time domain reflectometry whilst the cable or transmission line is any of open-circuited, short-circuited or terminated at the first end.

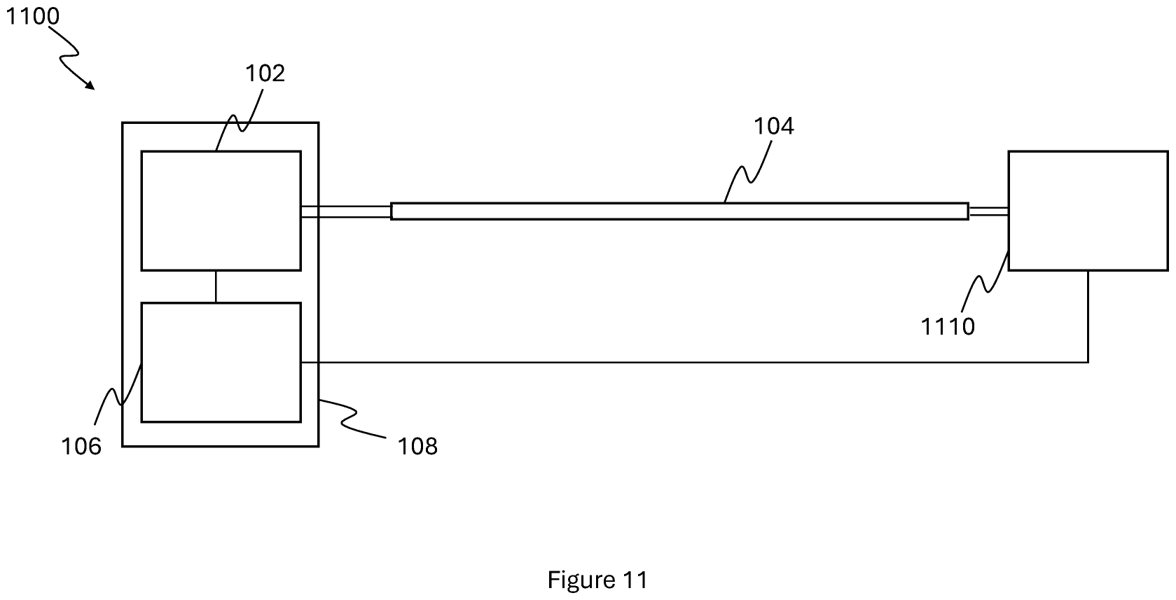

FIG. 11 shows the time domain reflectometer system, similar to that of FIG. 1, but further comprising a second time domain reflectometer 1110 coupled to the second end of the cable or transmission line 104. The second echo response obtained in step S1004 may be obtained by the second time domain reflectometer 1110 coupled to the second end of the cable or transmission line 104. The first time domain reflectometer 102 and the second time domain reflectometer 1110 may be the same time domain reflectometer. During use, the operator may couple the time domain reflectometer to the first end and then the second end of the cable or transmission line 104.

In step S1006 a plurality of reflections are identified in the first echo response and the second echo response.

In step 1010, the method comprises determining the presence of a first reflection with a negative polarity in the first echo response at a first distance from the first end of the cable or transmission line 104. If a first reflection having these properties is not present in the first echo response, then no shield fault is detected, and the method moves to step S1012.

When the method moves to step S1012, the method may finish, and as it has been determined that a shield-fault is not present.

If a first reflection is determined to be present in the first echo response having the referenced properties, then the method moves to step S1014. In step S1014, the method comprises determining the presence of a second reflection with a negative polarity in the second echo response at a second distance from the second end of the cable or transmission line 104.

If a second reflection is determined to be present in the second echo response having the referenced properties, then the method moves to step S1016. In step S1016, the method comprises determining the presence of a third reflection with a positive polarity in the first echo response at a third distance from the first end of the cable or transmission line 104. The third distance may equal twice the first distance. If a third reflection having these properties is not present in the first echo response, then no shield fault is detected, and the method moves to step S1012.

If a third reflection is determined to be present in the first echo response having the referenced properties, then the method moves to step S1018. In step S1018, the method comprises determining the presence of a fourth reflection with a positive polarity in the second echo response at a fourth distance from the first end of the cable or transmission line 104. The fourth distance may equal twice the second distance. If a fourth reflection having these properties is not present in the second echo response, then no shield fault is detected, and the method moves to step S1012.

If a fourth reflection is determined to be present in the second echo response having the referenced properties, then the method moves to step S1020. In step S1020, the method comprises determining whether a fifth reflection is present in the first echo response at a fifth distance from the first end of the cable or transmission line 104, the fifth distance equal to the first distance minus the second distance. The method further comprises determining whether a sixth reflection is present in the second echo response at a sixth distance from the second end of the cable or transmission line 104, the sixth distance is equal to the second distance minus the first distance. One of the measurements d1-d2 or d2-d1 will be a negative value. As such, where the operation relating to the negative distance may be immediately discarded, and the relevant one of the fifth or sixth reflection cannot be present. As such, only one of the fifth or sixth reflection needs to be checked for.

If the presence of at least one of the fifth and sixth reflections is determined, then no shield-fault is determined, and the method moves to step S1012. If neither of the fifth and the sixth reflections are determined to be present, then a shield fault is determined to be present and the method moves to step S1022. The shield fault is determined to be located at the first distance from the first end of the cable or transmission line 102, which corresponds to the second distance from the second end of the cable or transmission line 104.

The method of FIG. 8a determines the location of a shield-fault in dependence on knowledge of the length of the cable or transmission line 104. The length of the cable or transmission line 104 is obtained in step S808. The length of the cable or transmission line 104 may be a known quantity. For example, the length may be provided by the user of the time domain reflectometer. Alternatively, the length of the cable or transmission line 104 may be determined using the time domain reflectometer.

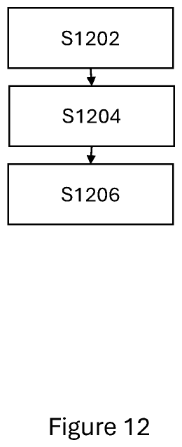

FIG. 12 is a flowchart of a method for determining the length of the cable or transmission line 104. The method may be performed by the control system 106 of the time domain reflectometry system 108, or by other suitable control systems, microprocessors or systems.

In step S1202 an open-circuit echo response of the cable or transmission line 104 is obtained from a first end of the cable or transmission line 104 using time domain reflectometry.

In step S1204 a terminated echo response of the cable or transmission line 104 is obtained from a first end of the cable or transmission line 104 using time domain reflectometry.

In step S1206, the length of the cable or transmission line is determined to be the length or distance at which a first reflection with a positive polarity is present in the open-circuit echo response and a second reflection with either a positive polarity or a negative polarity and a lesser (absolute) amplitude than the first reflection is present in the terminated echo response.

Determining the presence of a shield fault requires the identification of a plurality of reflections in the echo responses (see steps S606; S706; S806; S904; S1006). Identifying the presence and location of a reflection may comprise determining the location of the peak amplitude (absolute value) of the echo response. The identification of the plurality of reflections may comprise validating reflections within the echo responses and/or normalising reflections within the echo response.

As described with respect to FIG. 3, the amplitude of the reflections in the obtained echo response may vary due to the attenuation of the cable or transmission line 104. To ensure that reflections at different locations along the cable or transmission line 104 are comparable, the reflections may be normalised.

Obtaining the normalised representation of the reflections may comprise normalising the reflections of the echo response against an exponential function. As such, a normalised representation of the representation of the plurality of reflections is obtained, or a normalised representation of a fault threshold is obtained.

FIG. 13 is a graph showing the normalised representations of a plurality of reflections 1302-1314 which relate to the non-normalised reflections 302-314 shown in FIG. 3.

The echo responses shown in FIGS. 3 and 13 may be sampled discrete signals. The X axis shows the sample at which the reflection was detected, with a higher sample number indicating that the reflection occurs a greater distance along the cable from the time domain reflectometer. The Y axis shows the impulse response amplitude at each data point or amplitude of the reflection. Whilst the echo response is sampled, it is clear that the sample number may also be considered to be a time at which the reflection was detected, or a distance along the cable or transmission line 104.

The echo responses of FIG. 13 are normalised relative to the sample number, or an exponential function of the sample number of the reflection. This may also be considered to be the same as normalising the echo response against time or a distance from the time domain reflectometer.

The obtained echo responses may comprise both valid signals (indicative of faults or other events) and noise. As such, the identification of a plurality of reflections in the echo responses may comprise validating the reflections in the echo response.

A reflection may be determined to be invalid for a number of reasons. FIG. 13 shows the second reflection 1304 followed by a reflection 1318.

A reflection may be invalid if the reflection is adjacent to a preceding reflection and of an opposite polarity to the preceding reflection. As is shown in FIG. 13, the following reflection 1318 has an opposite polarity (negative) to the polarity of the second reflection 1304 (positive). Further, the following reflection may be invalid if the following reflection 1318 is adjacent to the second reflection 1304. Adjacent may mean that a final sample of the first reflection 1304 is adjacent to a first sample of the following reflection 1318. Adjacent may mean that the final sample of the first reflection and first sample of the following reflection are within a small number of samples of each other. This may be a threshold value, where if the first sample of the following reflection is within a following threshold sample number, then it is considered to be an overshoot or undershoot rather than an independent fault. This following threshold sample number may be determined through experimental testing of cables which include a single fault, to determine how many samples after the final sample of the reflection the following reflection occurs. For example, after the second reflection 1304 the echo response of the cable or transmission 104 line may not return to a steady state, but instead may overshoot or undershoot.

The sample at which the reflection crosses the zero-axis or has zero impulse response may define whether a sample is part of the reflection or part of an overshoot or undershoot. The final or end sample of a reflection and the first or start sample of the undershoot or overshoot may be defined as the samples either side of a sample where a zero crossing occurs. Alternatively, the start and end of a may be defined as a sample at which the absolute value of the slope or gradient is below a fraction of the average slope of the reflection. For instance, where the slope of a sample or number of samples is ¼^{th} of the average slope of the reflection. Where the polarity of the following reflection has an opposite polarity and is adjacent to a preceding reflection, it may be considered to be caused by an undershoot or overshoot and thus not representative of a fault.

The reflection 1318 may also be considered invalid if it has a width (the number of samples, time or distance between the first sample of a reflection and the final sample of the reflection) that is less than a sample width threshold. The sample width threshold may be defined through calibration based on the type or severity of fault that can be tolerated by a communication system. The sample width threshold may be defined as half the width of the smallest non-tolerable fault's sample width reflection.

The reflection 1318 may be considered invalid if the reflection is adjacent to a preceding reflection 1304 and has a smaller average starting differential or gradient than the preceding reflections ending differential or gradient. The starting differential of a reflection may be considered to be a gradient of the reflection between a start of the reflection and a peak amplitude of the reflection. The ending differential of a reflection may be a gradient of the reflection between a peak amplitude of the reflection and an end of the reflection. For example, the ending differential of the second reflection 1304 is the differential over the sample or time period between the first and last sample of the reflection. The starting differential of the reflection 1318 is the differential between the first and last sample of the reflection. The peak amplitude of a reflection is the maximum absolute value of the reflection. As the starting and ending differentials of adjacent reflections may be of opposite polarity, the comparison may be between absolute values of starting and ending reflections.

By considering these factors, it can be determined whether a following reflection is valid, or if it is simply an overshoot or undershoot related to a prior reflection.

Various modifications whether by way of addition, deletion, or substitution of features may be made to the above described examples to provide further examples, any and all of which are intended to be encompassed by the appended claims.

### Numbered Aspects:

By way of non-limiting example, some aspects of the disclosure are set out in the following numbered clauses.

1. A method for detecting a shield-fault in a cable or transmission line, the method comprising:
obtaining at least one echo response of the cable or transmission line from a first end of the cable or transmission line using time domain reflectometry, TDR;
identifying a plurality of reflections in the at least one echo response; and
determining the presence of a shield-fault by comparing locations of reflections in the at least one echo response.

2. The method for detecting a shield-fault in a cable or transmission line according to aspect 1,
wherein obtaining at least one echo response of the cable or transmission line from a first end of the cable or transmission line using TDR, comprises obtaining at least one of:
   an open-circuit echo response of the cable or transmission line from a first end of the cable or transmission line using TDR whilst the cable or transmission line is open-circuited at a second end;
   a terminated echo response of the cable or transmission line from the first end of the cable or transmission line using TDR whilst the cable or transmission line is terminated at the second end; or
   a short-circuit echo response of the cable or transmission line from a first end of the cable or transmission line using TDR whilst the cable or transmission line is short-circuited at the second end; and
wherein identifying a plurality of reflections in the at least one echo response comprises:
   identifying a plurality of reflections in at least one of the open-circuit echo response, the terminated echo response and the short-circuit echo response; and
wherein determining the presence of a shield-fault by comparing locations of reflections in the at least one echo response comprises:
   determining the presence of a shield-fault by comparing respective locations of reflections in the at least one of the open-circuit, the terminated and the short-circuit echo responses.

3. The method for detecting a shield-fault in a cable or transmission line according to aspect 2,
wherein determining the presence of a shield-fault comprises:
   determining the presence of a first reflection with a negative polarity in the terminated echo response at a first distance along the cable or transmission line, wherein if there is no first reflection, no shield fault is detected.

4. The method for detecting a shield-fault in a cable or transmission line according to aspect 3,
wherein determining the presence of a shield-fault comprises determining the presence of a second reflection having the following criteria:
   a positive or negative polarity in the open-circuit echo response at the first distance along the cable or transmission line, with a different amplitude than the first reflection; or
   a negative polarity in the short-circuit echo response at the first distance, with a larger absolute amplitude than the first reflection, and being the last reflection found in the short-circuit echo response,
   wherein if there is no second reflection, no shield fault is detected.

5. The method for detecting a shield-fault in a cable or transmission line according to aspect 4,
wherein determining the presence of a shield-fault comprises:
   determining the presence of a third reflection with a positive polarity in either the terminated or open-circuit echo response at a second distance along the cable or transmission line, wherein the second distance is twice the first distance; or
   wherein if there is no third reflection, no shield fault is detected.

6. The method for detecting a shield-fault in a cable or transmission line according to aspect 5, wherein if the presence of first, second, and third reflections are determined, a shield fault is located at the first distance along the cable or transmission line.

7. The method for detecting a shield-fault in a cable or transmission line according to aspect 2,
wherein determining the presence of a shield-fault comprises:
   determining the presence of a first reflection with a negative polarity in the terminated echo response at a first distance along the cable or transmission line,
   wherein if there is no first reflection, no shield fault is detected.

8. The method for determining a shield fault in a cable or transmission line according to aspect 7,
wherein determining the presence of a shield-fault comprises:
   determining the presence of a second reflection with a negative polarity in the open-circuit echo response at the first distance along the cable or transmission line, wherein the amplitude of the second reflection is the same as the amplitude and characteristics of the first reflection,
   wherein if there is no second reflection, no shield fault is detected.

9. The method for detecting a shield-fault in a cable or transmission line according to aspect 8,
wherein determining the presence of a shield-fault comprises:
   determining the presence of a third reflection with a positive polarity in the terminated echo response at a second distance along the cable or transmission line, wherein the second distance is twice the first distance;
   determining the presence of a fourth reflection with a positive polarity in the open-circuit echo response at the second distance along the cable or transmission line;
   wherein if there is no third reflection and no fourth reflection, no shield fault is detected, and
   wherein if the presence of first, second, and either of the third or fourth reflections are determined, a shield fault is located at the first distance along the cable or transmission line.

10. The method for detecting a shield-fault in a cable or transmission line according to any of aspects 7 to 9, wherein the method further comprises determining the length of the cable, and wherein the first distance is less than the length of the cable, wherein determining the length of the cable comprises:
determining the presence of:
   a fifth reflection with a positive polarity in the open-circuit echo response at a third distance along the cable or transmission line;
   a sixth positive polarity reflection in the terminated echo response at the third distance along the cable or transmission line with a lower absolute amplitude than the fifth reflection or negative polarity in the terminated echo response,
   wherein the length of the cable is the third distance.

11. The method for detecting a shield-fault in a cable or transmission line according to any of aspects 2-10,
wherein obtaining an open-circuit echo response of the cable or transmission line comprises disconnecting the second end of the cable or transmission line.

12. The method for detecting a shield-fault in a cable or transmission line according to any of aspects 2-10,
wherein obtaining an open-circuit echo response of the cable or transmission line comprises powering off a device coupled to the second end.

13. The method of detecting a shield-fault in a cable or transmission line according to any of aspects 2-12,
wherein obtaining a terminated echo response of the cable or transmission line comprises terminating the second end of the cable or transmission line with a load of the same impedance as the cable or transmission line.

14. The method for detecting a shield-fault in a cable or transmission line according to aspect 2,
wherein determining the presence of a shield-fault comprises:
   determining the presence of a first reflection with a positive polarity in the open-circuit echo response at a first distance, wherein the first distance is equal to twice a length of the cable or transmission line.
wherein if there is no first reflection, no shield fault is detected, and
wherein if the presence of the first reflection is determined, a shield fault is located at half the first distance along the cable or transmission line.

15. The method for detecting a shield-fault in a cable or transmission line according to aspect 2 or aspect 14, wherein determining the presence of a shield-fault comprises
determining the presence of a second reflection with a negative polarity in the terminated echo response at a second distance, the second distance equal to a length of the cable or transmission line,
wherein if there is no second reflection, no shield fault is detected.

16. The method for detecting a shield-fault in a cable or transmission line according to aspect 15, wherein determining the presence of a shield-fault comprises:
determining the presence of a third reflection with a positive polarity in the terminated echo response at a third distance, the third distance equal to twice the cable length,
wherein if there is no third reflection, no shield fault is detected, and
wherein if the presence of second and third reflections are determined, a shield fault is located at the second distance along the cable or transmission line.

17. The method for detecting a shield-fault in a cable or transmission line according to aspect 1, further comprising:
wherein obtaining at least one echo response of the cable or transmission line from a first end of the cable or transmission line using time domain reflectometry, TDR, comprises obtaining a first echo response of the cable or transmission line from the first end of the cable or transmission line;
obtaining a second echo of the cable or transmission line from a second end of the cable or transmission line using time domain reflectometry, TDR.

18. The method for detecting a shield-fault in the cable or transmission line according to aspect 17, further comprising:
determining the presence of a first reflection with a negative polarity in the first echo response at a first distance;
wherein if there is no first reflection, no shield fault is detected.

19. The method for detecting a shield-fault in the cable or transmission line according to aspect 18, further comprising:
determining the presence of a second reflection with a negative polarity in the second echo response at a second distance;
wherein if there is no second reflection, no shield fault is detected.

20. The method for detecting a shield-fault in the cable or transmission line according to aspect 19, further comprising:
determining the presence of a third reflection with a positive polarity in the first echo response at a third distance, the third distance equal to twice the first distance;
wherein if there is no third reflection, no shield fault is detected.

21. The method for detecting a shield-fault in the cable or transmission line according to aspect 20, further comprising:
determining the presence of a fourth reflection with a positive polarity in the second echo response at a fourth distance, the fourth distance equal to twice the second distance;
wherein if there is no fourth reflection, no shield fault is detected.

22. The method for detecting a shield-fault in the cable or transmission line according to aspect 21, further comprising:
determining the presence of fifth reflection in the first echo response at a fifth distance, the fifth distance equal to the first distance minus the second distance;
determining the presence of sixth reflection in the second echo response at a sixth distance, the sixth distance equal to the second distance minus the first distance;
wherein if the fifth reflection or the sixth reflection are determined, no shield fault is detected;
wherein if there is no fifth reflection and no sixth reflection, a shield fault is detected at the first distance from the first end of the cable or transmission line.

23. The method for detecting a shield-fault in a cable or transmission line according to any preceding aspect, further comprising:
validating the identified plurality of reflections in the at least one echo response.

24. A method for detecting a shield-fault in a cable or transmission line, the method comprising:
obtaining an open-circuit echo response of the cable or transmission line from a first end of the cable or transmission line using time domain reflectometry, TDR, whilst the cable or transmission line is open-circuited at a second end;
obtaining a terminated echo response of the cable or transmission line from the first end of the cable or transmission line using TDR whilst the cable or transmission line is terminated at the second end;
obtaining a short-circuit echo response of the cable or transmission line from the first end of the cable or transmission line using TDR whilst the cable or transmission line is short-circuited at the second end;
identifying a plurality of reflections in the open-circuit echo response, the terminated echo response, and the short-circuit echo response
determining the presence of a shield-fault by comparing respective locations of reflections in the open-circuit, terminated and, short-circuit echo responses.

25. A method for detecting a shield-fault at the end of a cable or transmission line, the method comprising:
obtaining a terminated echo response of the cable or transmission line from a first end of the cable or transmission line using time domain reflectometry, TDR;
identifying a plurality of reflections in the echo response;
determining the presence of a shield-fault, wherein a shield-fault is determined if:
   a negative polarity reflection is present at a first distance, the first distance equal to a length of the cable or transmission line;
   a positive polarity reflection is present at a second distance, the second distance equal to twice the cable length.

1. A method for detecting a shield-fault in a cable or transmission line, the method comprising:
obtaining at least one echo response of the cable or transmission line from a first end of the cable or transmission line using time domain reflectometry, TDR;
identifying a plurality of reflections in the at least one echo response; and
determining a presence of a shield-fault by comparing locations of reflections in the at least one echo response.

2. The method for detecting a shield-fault in a cable or transmission line according to claim 1,
wherein obtaining at least one echo response of the cable or transmission line from a first end of the cable or transmission line using TDR, comprises obtaining at least one of:
an open-circuit echo response of the cable or transmission line from a first end of the cable or transmission line using TDR whilst the cable or transmission line is open-circuited at a second end;
a terminated echo response of the cable or transmission line from the first end of the cable or transmission line using TDR whilst the cable or transmission line is terminated at the second end; or
a short-circuit echo response of the cable or transmission line from a first end of the cable or transmission line using TDR whilst the cable or transmission line is short-circuited at the second end; and
wherein identifying a plurality of reflections in the at least one echo response comprises:
identifying a plurality of reflections in at least one of the open-circuit echo response, the terminated echo response and the short-circuit echo response; and
wherein determining the presence of a shield-fault by comparing locations of reflections in the at least one echo response comprises:
determining the presence of a shield-fault by comparing respective locations of reflections in the at least one of the open-circuit, the terminated and the short-circuit echo responses.

3. The method for detecting a shield-fault in a cable or transmission line according to claim 2,
wherein determining the presence of a shield-fault comprises:
determining the presence of a first reflection with a negative polarity in the terminated echo response at a first distance along the cable or transmission line, wherein if there is no first reflection, no shield fault is detected.

4. The method for detecting a shield-fault in a cable or transmission line according to claim 3,
wherein determining the presence of a shield-fault comprises determining the presence of a second reflection having at least one of:
a positive or negative polarity in the open-circuit echo response at the first distance along the cable or transmission line, with a different amplitude than the first reflection; or
a negative polarity in the short-circuit echo response at the first distance, with a larger absolute amplitude than the first reflection, and being the last reflection found in the short-circuit echo response,
wherein if there is no second reflection, no shield fault is detected.

5. The method for detecting a shield-fault in a cable or transmission line according to claim 4,
wherein determining the presence of a shield-fault comprises:
determining the presence of a third reflection with a positive polarity in either the terminated or open-circuit echo response at a second distance along the cable or transmission line, wherein the second distance is twice the first distance,
wherein if there is no third reflection, no shield fault is detected.

6. The method for detecting a shield-fault in a cable or transmission line according to claim 5, wherein if the first, second, and third reflections are determined to be present, a shield fault is located at the first distance along the cable or transmission line.

7. The method for detecting a shield-fault in a cable or transmission line according to claim 2,
wherein determining the presence of a shield-fault comprises:
determining the presence of a first reflection with a negative polarity in the terminated echo response at a first distance along the cable or transmission line,
wherein if there is no first reflection, no shield fault is detected.

8. The method for detecting a shield-fault in a cable or transmission line according to claim 7,
wherein determining the presence of a shield-fault comprises:
determining the presence of a second reflection with a negative polarity in the open-circuit echo response at the first distance along the cable or transmission line, wherein an amplitude of the second reflection is the same as the amplitude and characteristics of the first reflection,
wherein if there is no second reflection, no shield fault is detected.

9. The method for detecting a shield-fault in a cable or transmission line according to claim 8,
wherein determining the presence of a shield-fault comprises:
determining the presence of a third reflection with a positive polarity in the terminated echo response at a second distance along the cable or transmission line, wherein the second distance is twice the first distance;
determining the presence of a fourth reflection with a positive polarity in the open-circuit echo response at the second distance along the cable or transmission line;
wherein if there is no third reflection and no fourth reflection, no shield fault is detected, and
wherein if the first, second, and either of the third or fourth reflections are determined to be present, a shield fault is located at the first distance along the cable or transmission line.

10. The method for detecting a shield-fault in a cable or transmission line according to claim 2,
wherein determining the presence of a shield-fault comprises:
determining the presence of a first reflection with a positive polarity in the open-circuit echo response at a first distance, wherein the first distance is equal to twice a length of the cable or transmission line,
wherein if there is no first reflection, no shield fault is detected, and
wherein if the presence of the first reflection is determined, a shield fault is located at half the first distance along the cable or transmission line.

11. The method for detecting a shield-fault in a cable or transmission line according to claim 2, wherein determining the presence of a shield-fault comprises:
determining the presence of a second reflection with a negative polarity in the terminated echo response at a second distance, the second distance equal to a length of the cable or transmission line,
wherein if there is no second reflection, no shield fault is detected.

12. The method for detecting a shield-fault in a cable or transmission line according to claim 11, wherein determining the presence of a shield-fault comprises:
determining the presence of a third reflection with a positive polarity in the terminated echo response at a third distance, the third distance equal to twice the cable length,
wherein if there is no third reflection, no shield fault is detected, and
wherein if the second and third reflections are determined to be present, a shield fault is located at the second distance along the cable or transmission line.

13. The method for detecting a shield-fault in a cable or transmission line according to claim 1, further comprising:
wherein obtaining at least one echo response of the cable or transmission line from a first end of the cable or transmission line using time domain reflectometry, TDR, comprises obtaining a first echo response of the cable or transmission line from the first end of the cable or transmission line;
obtaining a second echo of the cable or transmission line from a second end of the cable or transmission line using time domain reflectometry, TDR.

14. The method for detecting a shield-fault in the cable or transmission line according to claim 13, further comprising:
determining the presence of a first reflection with a negative polarity in the first echo response at a first distance;
wherein if there is no first reflection, no shield fault is detected.

15. The method for detecting a shield-fault in the cable or transmission line according to claim 14, further comprising:
determining the presence of a second reflection with a negative polarity in the second echo response at a second distance;
wherein if there is no second reflection, no shield fault is detected.

16. The method for detecting a shield-fault in the cable or transmission line according to claim 15, further comprising:
determining the presence of a third reflection with a positive polarity in the first echo response at a third distance, the third distance equal to twice the first distance;
wherein if there is no third reflection, no shield fault is detected.

17. The method for detecting a shield-fault in the cable or transmission line according to claim 16, further comprising:
determining the presence of a fourth reflection with a positive polarity in the second echo response at a fourth distance, the fourth distance equal to twice the second distance;
wherein if there is no fourth reflection, no shield fault is detected.

18. The method for detecting a shield-fault in the cable or transmission line according to claim 17, further comprising:
determining the presence of fifth reflection in the first echo response at a fifth distance, the fifth distance equal to the first distance minus the second distance;
determining the presence of sixth reflection in the second echo response at a sixth distance, the sixth distance equal to the second distance minus the first distance;
wherein if the fifth reflection or the sixth reflection are determined to be present, no shield fault is detected;
wherein if there is no fifth reflection and no sixth reflection, a shield fault is detected at the first distance from the first end of the cable or transmission line.

19. A method for detecting a shield-fault in a cable or transmission line, the method comprising:
obtaining an open-circuit echo response of the cable or transmission line from a first end of the cable or transmission line using time domain reflectometry, TDR, whilst the cable or transmission line is open-circuited at a second end;
obtaining a terminated echo response of the cable or transmission line from the first end of the cable or transmission line using TDR whilst the cable or transmission line is terminated at the second end;
obtaining a short-circuit echo response of the cable or transmission line from the first end of the cable or transmission line using TDR whilst the cable or transmission line is short-circuited at the second end;
identifying a plurality of reflections in the open-circuit echo response, the terminated echo response, and the short-circuit echo response;
determining a presence of a shield-fault by comparing respective locations of reflections in the open-circuit, terminated and, short-circuit echo responses.

20. A method for detecting a shield-fault at an end of a cable or transmission line, the method comprising:
obtaining a terminated echo response of the cable or transmission line from a first end of the cable or transmission line using time domain reflectometry, TDR;
identifying a plurality of reflections in the echo response;
determining a presence of a shield-fault, wherein a shield-fault is determined if:
a negative polarity reflection is present at a first distance in the terminated echo response, the first distance equal to a length of the cable or transmission line;
a positive polarity reflection is present at a second distance in the terminated echo response, the second distance equal to twice the cable length.
